(19) United States
(12) Patent Application Publication
(10) Pub. No.: US 2017/0040442 A1
(43) Pub. Date: Feb. 9, 2017

(54) IGBT

(71) Applicant: TOYOTA JIDOSHA KABUSHIKI KAISHA, Toyota-shi (JP)

(72) Inventors: Yasuhiro HIRABAYASHI, Nagoya-shi (JP); Masaru SENOO, Okazaki-shi (JP)

(73) Assignee: TOYOTA JIDOSHA KABUSHIKI KAISHA, Toyota-shi (JP)

(21) Appl. No.: 15/229,603

(22) Filed: Aug. 5, 2016

(30) Foreign Application Priority Data
Aug. 7, 2015 (JP) 2015-157327

(51) Int. Cl. H01L 29/739; H01L 29/06; H01L 29/10

(52) U.S. Cl. CPC H01L 29/7397; H01L 29/1095; H01L 29/0696

(57) ABSTRACT

An IGBT comprises emitter regions, a collector region, a drift region and a body region in a semiconductor substrate. The semiconductor substrate comprises a trench extending from the front surface of the semiconductor substrate and reaching the drill region. The trench partitions the front surface of the semiconductor substrate into a plurality of blocks in a plan view of the semiconductor substrate. The plurality of the blocks comprises cell blocks, each of which is partitioned to be smaller than a predetermined area by the trench, and a surrounding block which is a region other than the cell blocks. The collector region, the drift region, the body region and the emitter region are provided in each of the cell blocks and the surrounding block. A total area of the emitter regions in the cell blocks is greater than a total area of the emitter region in the surrounding block.

### CROSS-REFERENCE TO RELATED APPLICATION

This application claims priority to Japanese Patent Application No. 2015-157327 filed on Aug. 7, 2015, the entire contents of which are hereby incorporated by reference into the present application.

### TECHNICAL FIELD

The present disclosure herein relates to an IGBT (Insulated Gate Bipolar Transistor).

### DESCRIPTION OF RELATED ART

A vertical IGBT that uses a trench gate electrode is known. The vertical IGBT provides an emitter electrode on a front surface of a semiconductor substrate (a side on which the emitter electrode is provided will be termed the front surface), provides a collector electrode on a back surface of the semiconductor substrate (a side on which the collector electrode is provided will be termed the back surface), a trench that extends from the front surface of the semiconductor substrate toward the back surface thereof is provided, and the gate electrode is accommodated in the trench.

A technique that provides a matrix-shaped trench that includes lengthwise and breadthwise trenches extending perpendicular to each other when a semiconductor substrate is seen in a plan view is known. The matrix-shaped trench partitions a front surface of the semiconductor substrate into a plurality of blocks. In this technique, an emitter region and a body contact region are provided in each of cell blocks defined by being surrounded by the matrix-shaped trench. By using the matrix-shaped trench defining the cell blocks, a carrier accumulating effect in the cell blocks is increased, and their on-voltage is reduced. An example of such a technique is disclosed in Japanese Patent Application Publication No. 2013-150000.

### SUMMARY

The on-voltage may be improved by the technique that partitions the front surface of the semiconductor substrate into the plurality of blocks by the matrix-shaped trench, however, a breakage resistance may be decreased in some cases. An investigation was conducted on the cause thereof; and the following finding was achieved.

FIG. 4 shows a cross sectional view of a boundary between cell blocks 6 defined by being surrounded by a trench 4 extending in a matrix shape when seen in a plan view and a surrounding block 18 that is not surrounded by the trench 4. Reference sign 8 denotes an emitter region in each cell block 6, 10 denotes a body contact region in each cell block 6, 20 denotes an emitter electrode, 22 demotes a body region, 24 denotes a carrier accumulating layer, 26 denotes a drift region, 28 denotes a buffer region, 30 denotes a collector region, 32 denotes a collector electrode, 34 denotes an interlayer insulating film, 36 denotes a gate insulating film, and 38 denotes a gate electrode. The left side of the trench 4 in FIG. 4 is the surrounding block 18 that is not surrounded by the trench 4, and an emitter region and a body contact region are not provided, therein. However, the body region 22, the drift region 26, the collector region 30 extend uniformly over the cell blocks 6 and the surrounding block 18.

When an IGBT of FIG. 4 turns on, electrons are injected to the drift region 26 through an inversion layer generated from the emitter regions 8 in the cell blocks 6 along the trench 4, while on the other hand holes are injected to the drift region 26 from the collector region 30. The electrons and holes generate a phenomenon of conductivity modulation. The holes injected to the drift region 26 are discharged to the emitter electrode 20 through the body contact regions 10.

As shown in FIG. 4, the holes are injected from the collector region 30 to the drift region 26 in the surrounding block 18 as well. As a result, the holes migrate from the surrounding block 18 to the cell blocks 6, and are discharged to the emitter electrode 20 from the body contact regions 10 in the cell blocks 6. At the boundary of the cell blocks 6 and the surrounding block 18, a phenomenon has been found in which the holes migrate from the surrounding block 18 to the cell blocks 6 and the holes concentrate at positions below the body contact regions 10. Local heat generation occurs due to this concentration of the holes, and it has been found that the breakage resistance decreases due to this phenomenon.

In this disclosure, an IGBT that can suppress a generation of the aforementioned phenomenon of hole concentration is disclosed. Notably, an IGBT referred herein is not limited to a semiconductor device in which only the IGBT is provided in a single semiconductor substrate, but may be a semiconductor device (RCIGBT) in which an IGBT and a diode are provided in a single semiconductor substrate.

The IGBT disclosed herein comprises a semiconductor substrate, an emitter electrode provided on a front surface of the semiconductor substrate, and a collector electrode provided on a back surface of the semiconductor substrate. The semiconductor substrate comprises emitter regions of a first conductive type that are electrically connected to the emitter electrode; a collector region of a second conductive type that is electrically connected to the collector electrode; a drift region of the fast conductive type that is separated from the collector electrode by the collector region; and a body region of the second conductive type that separates the emitter regions and the drift region. The semiconductor substrate further comprises a trench extending from the front surface of the semiconductor substrate and reaching the drift region. The trench extends lengthwise and breadthwise in a matrix shape, and partitions the front surface of the semiconductor substrate into a plurality of blocks in a plan view of the semiconductor substrate.

In the present disclosure, blocks that are partitioned to be equal to or smaller than a predetermined area by the trench are termed cell blocks, and a region other than that, namely, a region that is not surrounded by the trench, and any region that has an area that is greater than the predetermined area despite being defined and surrounded by the trench, will be termed a surrounding block. The predetermined area described herein is set to an area by which a carrier accumulating effect can be achieved if the block area is set to be equal to or smaller, and by which the carrier accumulating effect cannot be achieved if the block, area is set to be greater.

In the IGBT disclosed herein, the collector region, the drift region, the body region and the emitter region are provided in each of the cell blocks and the surrounding block. Moreover, a relationship is set in which a total area of the emitter regions in the cell blocks is greater than a total area of the emitter region in the surrounding block in the plan view of the semiconductor substrate.

In the IGBT disclosed herein, the emitter region is provided also in the surrounding block, and electrons are injected from the emitter region to the drift region in the surrounding block as well. Holes that have been injected to the drift region of the surrounding block from the collector region of the surrounding block remain within the surrounding block by being influenced by the electrons, and their migration to the cell blocks is greatly inhibited. A phenomenon in which the holes migrate from the surrounding block to the cell blocks is suppressed, and a phenomenon in which the holes accumulate excessively in the cell blocks is suppressed.

Further, since the relationship in which the total area of the emitter regions in the cell blocks is greater than the total area of the emitter region in the surrounding block is established, carriers flow primarily through the cell blocks. In the cell blocks, an on-voltage can be reduced by the carrier accumulating effect therein.

In the IGBT disclosed herein:
(1) in addition to the relationship that the total area of the emitter regions in the cell blocks is greater than the total area of the emitter region in the surrounding block as aforementioned,
(2) it is preferable to have a relationship that a total area of the cell blocks is greater than a total area of the surrounding block. When this relationship is established, the phenomenon in which the carriers flow primarily through the cell blocks can surely be achieved.

Alternatively:
(3) it is alternatively or additionally effective to set a relationship that an area ratio of the emitter regions occupying the blocks is high for the cell blocks and low for the surrounding block. When this relationship is established, the phenomenon in which the carriers are accumulated in the cell blocks can surely be achieved, and the on-voltage can be reduced.

The relationships of above (2) and (3) are preferably satisfied simultaneously, however, only one of the (2) and (3) may be satisfied. This selection can be made according to a performance required for a semiconductor device.

According to the IGBT disclosed herein, the on-voltage can be reduced by utilizing the matrix-shaped trench, and the excessive hole accumulation can be suppressed by causing the holes to have less mobility to migrate from the surrounding block to the cell blocks. An IGBT having a low on-voltage and a high breakage resistance can be achieved.

The details and further improvements made to the techniques disclosed herein will further be described in the below detailed description.

### BRIEF DESCRIPTION OF DRAWINGS

FIG. 1 is a plan view of an IGBT of a first embodiment;

FIG. 2 is a partial enlarged view of FIG. 1;

FIG. 3 is a cross sectional view along a line III-III of FIG. 2;

FIG. 4 is a cross sectional view of a conventional device corresponding to FIG. 3;

FIG. 5 is a plan view of an IGBT of a second embodiment;

FIG. 6 is a plan view of an IGBT of a third embodiment;

FIG. 7 is a plan view of an IGBT of a fourth embodiment;

FIG. 8 is a plan view of an IGBT of a fifth embodiment;

FIG. 9 is a plan view of an IGBT of a sixth embodiment;

FIG. 10 is a plan view of an IGBT of a seventh embodiment;

FIG. 11 is a plan view of an IGBT of an eighth embodiment;

FIG. 12 is a plan view of an IGBT of a ninth embodiment;

### DETAILED DESCRIPTION

Some of the features of the below-described embodiments will be listed.

(Feature 1) A region outside a contour defining a range where a plurality of square-shaped cell blocks is arranged consecutively is a surrounding block, and an emitter region and a body contact region are provided at least at a part of the surrounding block.
(Feature 2) The contour is square-shaped, and at least one pair of the emitter region and the body contact region is provided on each side of the square contour.
(Feature 3) A plurality of cell blocks is arranged consecutively along one or more of the sides, and the pair of the emitter region and the body contact region is provided in the surrounding block corresponding to each cell block.
(feature 4) A plurality of square-shaped cell blocks is arranged consecutively along a x direction as well as along a y direction.
(Feature 5) A plurality of square-shaped cell blocks is arranged consecutively along the x direction, and the aforementioned arrangement of the cell blocks appear repeatedly while being separated from each other along the y direction.
(Feature 6) An emitter region is provided at least at a part of the surrounding block. A body contact region is omitted therein.

### EMBODIMENTS

### First Embodiment

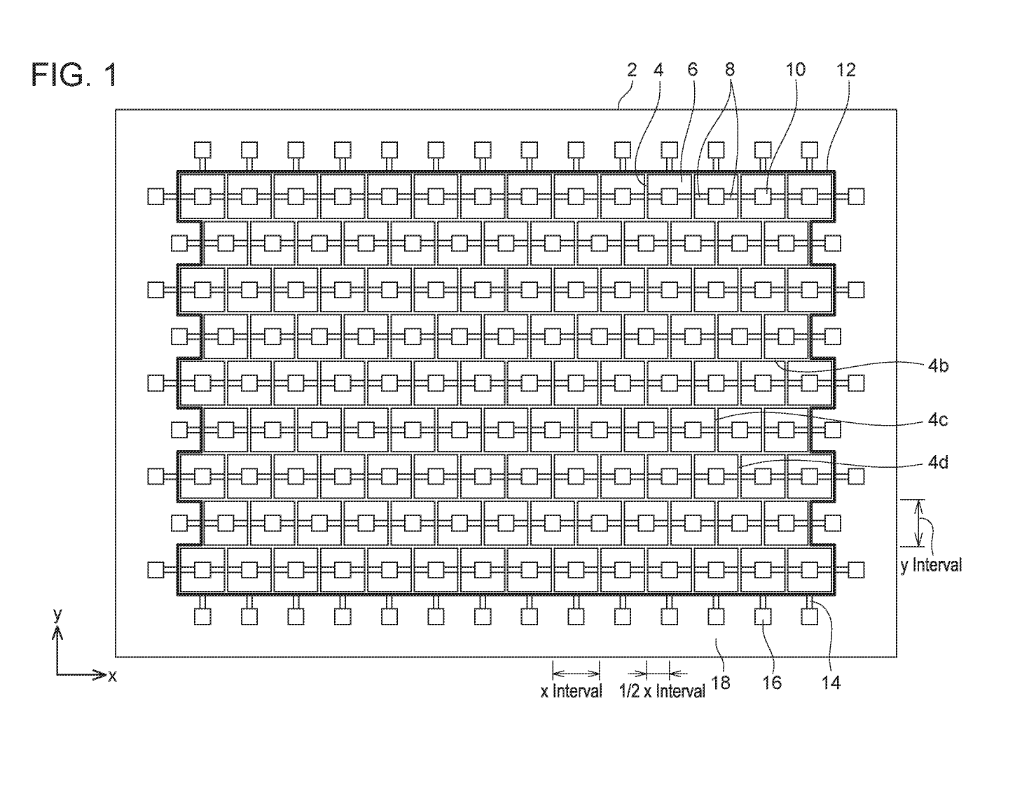

FIG. 1 is a plan view of an IGBT of a first embodiment. Reference sign 2 denotes a semiconductor substrate, 4 denotes a trench, 6 denotes a cell block, 8 denotes an emitter region in a cell block, 10 denotes a body contact region in a cell block, 12 denotes a contour that defines a range where cell blocks 6 are arranged consecutively, 14 denotes an emitter region provided in a surrounding block (region outside the contour 12), 16 denotes a body contact region provided in a surrounding block, and 18 denotes a surrounding block.

In this disclosure, two directions that are perpendicular to each other in a plan view of the semiconductor substrate are defined as an x direction and a y direction. The trench 4 is configured of a plurality of x trenches 4b extending in the x direction and spaced apart at predetermined y intervals in the y direction, and a plurality of y trenches 4c, 4d extending in the y direction and spaced apart at predetermined x intervals in the x direction. X-directional positions of y trenches 4c, 4d, which are adjacent in the y direction, are offset each other by ½ of the x interval. In other words, the y trenches comprise a first set of y trenches adjacent in the x direction and a second set of y trenches adjacent in the x direction. The first set of y trenches extends between a first pair of adjacent x trenches and the second set of y trenches extends between a second pair of adjacent x trenches, the first pair of adjacent x trenches being adjacent to the second pair of adjacent x trenches in the y direction. The first set of y trenches is offset by ½ of the x interval from the second set of y trenches in the x direction. The cell blocks 6 have a square shape that is defined and surrounded by the x trenches and the y trenches. Plural cell blocks 6 are provided consecutively within the contour 12. The contour 12 defines a range where the plural cell blocks 6 are arranged consecutively in the x direction and the y direction.

In the drawings, the reference signs are given only to some of the x trenches, the y trenches, the cell blocks, the emitter regions in the cell blocks, the body contact regions in the cell blocks, the emitter regions in the surrounding block, and the body contact regions in the surrounding block, however, they are arranged by a repetitive pattern on a front surface of the semiconductor substrate 2.

As viewed along the contour 12, plural cell blocks 6 are arranged repeatedly in the x direction and the y direction. In the first embodiment, the emitter regions 14 and the body contact regions 16 are provided in the surrounding block 18 at positions along outermost x trenches in the y direction and corresponding respectively to the cell blocks 6. Similarly, the emitter regions 14 and the body contact regions 16 are also provided in the surrounding block 18 at positions along outermost y trenches in the x direction and corresponding respectively to the cell blocks 6.

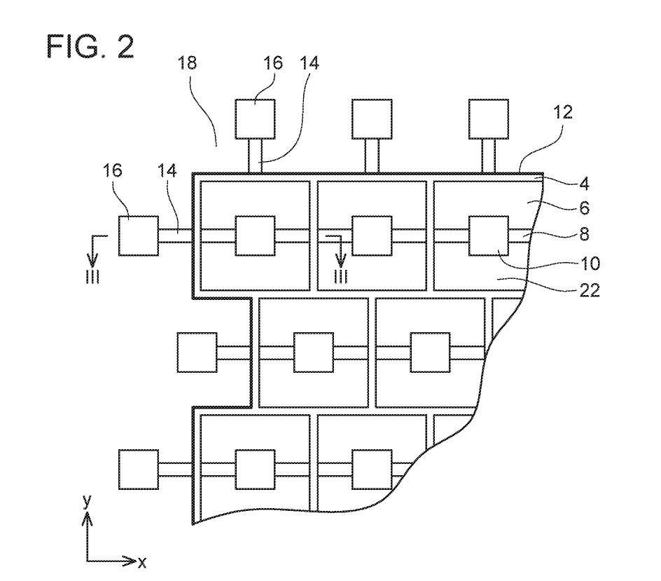

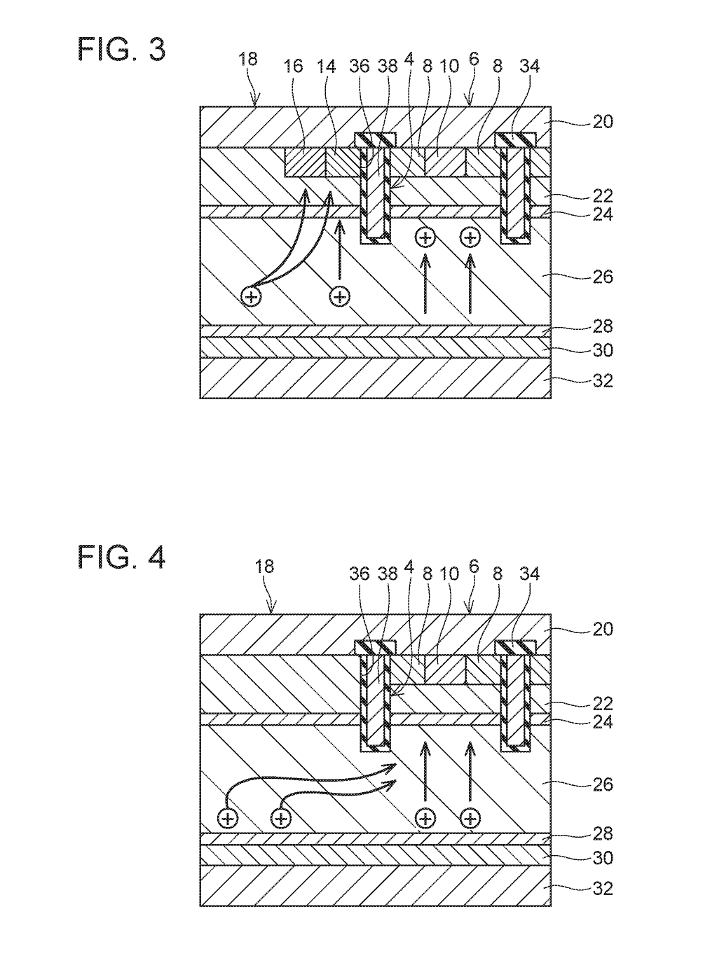

FIG. 2 shows an enlarged view of a left upper portion of FIG. 1, and FIG. 3 shows a cross sectional view along a line III-III of FIG. 2. As shown in FIG. 3, the emitter electrode 20 is provided on the front surface of the semiconductor substrate 2, and the collector electrode 32 is provided on a back surface of the semiconductor substrate 2. In the first embodiment, a first conductive type is an n-type, and a second conductive type is a p-type.

The p-type collector region 30 is provided at a range exposed on the back surface of the semiconductor substrate 2. The collector region 30 is configured to electrically connect to the collector electrode 32. The n-type buffer region 28 is provided on a front surface side of the collector region 30, and the n-type drift region 26 is provided on the front surface side of the buffer region 28. The buffer region 28 and the drift region 26 are separated from the collector electrode 32 by the collector region 30. The buffer region 28 may be omitted, or alternately be considered as a part of the drift region 26.

The trench 4 reaches the drift region 26 from the front surface of the semiconductor substrate 2. As shown in FIG. 1 and FIG. 2, each of the cell blocks 6 is defined and surrounded by the trench 4. The trench 4 that defines and surrounds the cell blocks 6 extend lengthwise and breadthwise to form a matrix defining and surrounding the cell blocks 6.

When an inside of each cell block 6 is seen in its cross sectional view, the n-type emitter regions 8 are provided at positions Adjacent to the trench 4 and exposed on the front surface. The emitter regions 8 are configured to be electrically connected with the emitter electrode 20. The p-type body contact region 10 is provided at a position in between the emitter regions 6 and exposed on the front surface. The body contact region 10 is also configured to be electrically connected with the emitter electrode 20. The p-type body region 22 is provided under the emitter regions 6 and the body contact region 10. The body region 22 separates the emitter regions 8 and the drift region 26, and is configured to be electrically connected to the body contact region 10. The body region 22 faces the trench 4. In the first embodiment, the n-type carrier accumulating region 24 is provided between the body region 22 and the drift region 26. The carrier accumulating region 24 increases a hole concentration in the drift region 26 during when the IGBT is on, and reduces an on-voltage. The carrier accumulating region 24 may be omitted. A side surface and a bottom surface of the trench 4 are covered by the gate insulating film 36, inside of which the gate electrode 38 is filled. An upper surface of the gate electrode 38 is covered by the interlayer insulating film 34.

A p-type impurity concentration contained in the body region 22 is low, and when a positive voltage is applied to the gate electrode 38, the body region 22 facing the gate electrode 38 via the gate insulating film 6 inverts to the n type so as form a channel, by which the emitter regions 8 and the drift region 26 become electrically connected. Electrons are injected to the drift region 26 from the emitter electrode 20 through die emitter regions 8 and the channel. In the meantime, holes are injected to the drift region 26 from the collector electrode 32 through the collector region 30. In the drift region 26, a phenomenon of conductivity modulation is generated, and a voltage difference (on-voltage) between the emitter electrode 20 and the collector electrode 32 is thereby decreased.

The collector electrode 32, the collector region 30, and the drift region 26 are provided also in the surrounding block 18, and in a state where a current flows between the emitter electrode 20 and the collector electrode 32, the holes are also injected to the drift region 26 of the surrounding block 18. In the present embodiment, the emitter regions 14 and the body contact regions 16 are provided also in the surrounding block 18. The electrons are injected to the drift region 26 of the surrounding block 18 from the emitter regions 14. The holes injected to the drift region 26 of the surrounding block 18 remain within the surrounding block 18 by being influenced by the electrons injected into the drift region 26 of the surrounding block 18. The holes that had remained in the surrounding block 18 are discharged to the emitter electrode 20 through the body region 22 and the body contact regions 16 of the surrounding block 18. A phenomenon in which the holes migrate from the surrounding block 18 to the cell blocks 6 is suppressed, and the generation of the phenomenon of hole accumulation shown in FIG. 4 is suppressed. The phenomenon in which the holes accumulate locally is suppressed, and the decrease in a breakage resistance can be prevented.

To prevent the holes from migrating from the surrounding block 18 to the cell blocks 6, the emitter regions 14 simply need to be provided in the surrounding block 18, and the body contact regions 16 in the surrounding block 18 are not mandatory. The holes are discharged to the emitter electrode 20 even without the body contact regions 16, if a barrier between the body region 22 and the emitter electrode 20 is low. Even in a case where the barrier between the body region 22 and the emitter electrode 20 is high, the formation of the body contact regions 16 may be omitted. In this case as well, the holes injected to the drift region 26 of the surrounding block 18 remain within the surrounding block 18 by being influenced by the electrons injected into the drift region 26 of the surrounding block 18 from the emitter regions 14 of the surrounding block 18. Even if the holes injected to the drift region 26 of the surrounding block 18 are not discharged smoothly to the emitter electrode 20, the holes do not migrate to the cell blocks 6 and accumulate therein. When the holes are not discharged from the drift region 26 of the surrounding block 18 and the holes are accumulated in the drift region 26 of the surrounding block 18, it becomes more difficult for the holes to be injected from the collector region 30 to the drift region 26 of the surrounding block 18, however, no particular problem rises due to this. Nonetheless, it is advantageous to provide the body contact regions 16 in the case where the barrier between the body region 22 and the emitter electrode 20 is high. It is preferable to have the emitter regions 14 and the body contact regions 16 arranged adjacently in the surrounding block 18 as well. By arranging as such, the holes are absorbed by the electrons injected from the emitter regions 14, and are efficiently discharged from the body contact regions 16. It is also preferable for an arrangement relationship between the emitter regions 14 and the body contact regions 16 in the surrounding block 18 to be similar to an arrangement relationship between the emitter regions 8 and the body contact regions 10 in the cell blocks 6. In this case, a carrier distribution is equalized among the cell blocks 6 and the surrounding block 18, and the phenomenon of hole accumulation car significantly be suppressed.

In the IGBT of the first embodiment, as is shown clearly in FIG. 2, the emitter regions 8 in each cell block 6 are arranged at positions connecting to the y trenches. Contrary to this, parts of the emitter regions 14 and the body contact regions 16 in the surrounding block 18 are provided at positions connecting to the x trenches that are located on the outermost sides in the y direction. When the aforementioned relationships are established, the carrier distribution in the cell blocks 6 positioned on the outermost sides in the y direction and the carrier distribution in the surrounding block 18 are equalized, and the phenomenon of hole accumulation can significantly be suppressed.

In addition, each of the emitter regions 14 in the surrounding block 18 provided at the positions connecting to the outermost x trenches is provided at an intermediate position between two adjacent y trenches. In this relationship, the carrier distribution in the cell blocks 6 positioned on the outermost sides in the y direction and the carrier distribution in the surrounding block 18 are well equalized, and the phenomenon of hole accumulation can significantly be suppressed at a greater degree.

As shown in FIG. 2, in the IGBT of the first embodiment, the emitter regions 14 and the body contact regions 16 of the surrounding block 18 are provided also on an outer side of the y trenches located on the outermost sides in the x direction. In this case, the holes can be prevented from migrating from the surrounding block 18 in the x direction into the cell blocks 6, as a result of which the breakage resistance is improved. Depending on conditions, there may be cases where the migration of the holes in the x direction does not become problematic. In such cases, the formation of the emitter regions 14 and the body contact regions 16 on the outer side of the outermost y trenches can be omitted.

As shown in FIG. 2, an area of each cell block 6 is equal to each other. Each cell block 6 is set to have an area equal to or smaller than an area by which the carrier accumulation effect can be achieved and an on-resistance can be decreased within the cell block.

In each of the cell blocks 6, the emitter regions 8, the body contact region 10, and the body region 22 are exposed on the front surface of the semiconductor substrate 2. An area ratio of the emitter regions 8 in each cell block 6, that is, a value achieved by: exposed area of emitter regions 8/(exposed area of emitter regions 8+exposed area of the body contact region 10+exposed area of the body region 22) is identical.

An area ratio of the emitter regions 14 in the surrounding block 18, that is, a value achieved by: (total exposed area of emitter regions 14/area of the surrounding block 18) can also be calculated.

In the present embodiment, a relationship is established by the former area ratio the latter area ratio. That is, in the cell blocks 6, the conductivity modulation is made active to reduce the on-resistance by injecting large amounts of electrons and holes. The surrounding block 18 does not fail the carrier accumulating effect of the cell blocks 6. However, if the emitter regions 14 are not provided in the surrounding block 18, there may be a case where the IGBT is damaged by an excessive hole accumulation. The former area ratio is determined by a balance between the area ratios, where the surrounding block 18 does not fail the carrier accumulating effect in the cell blocks 6, and the result of reducing the on-resistance in the cell blocks 6 by making use of the carrier accumulating effect and avoiding the excessive hole accumulation in the cell blocks 6 is successfully achieved. The area ratio of the emitter regions 14 in the surrounding block 18 can be adjusted to various values as will be described below.

In the present embodiment, the total area of the emitter regions 8 in the cell blocks 6 satisfies a relationship of being greater than a total area of the emitter regions 14 in the surrounding block 18. Furthermore, a relationship in which a total area of the cell blocks 6 is greater than a total area of the surrounding block 18 is also satisfied. The carriers primarily flow through the cell blocks 6.

### Second Embodiment

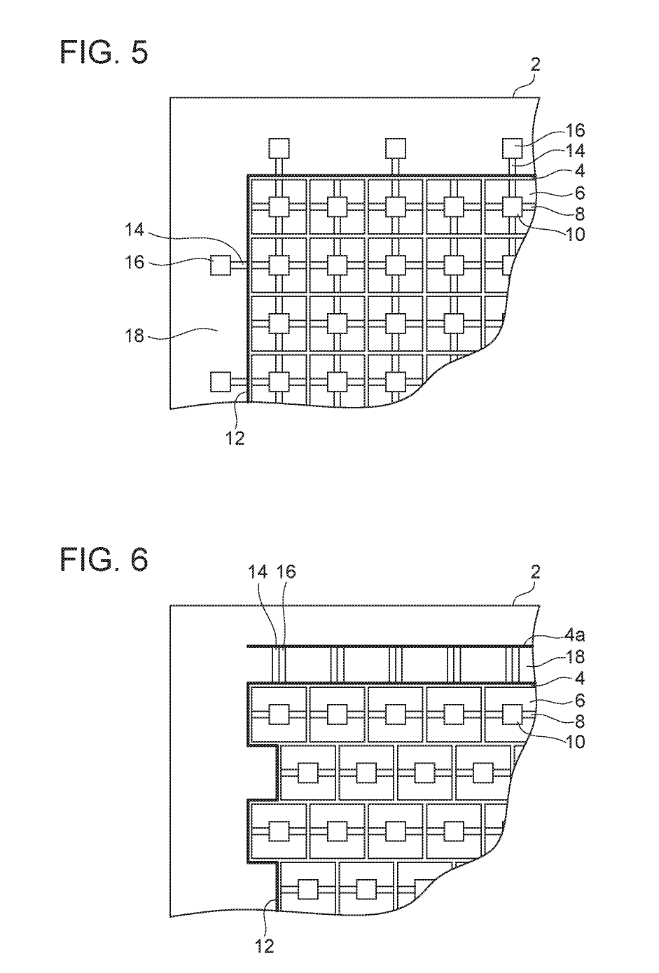

The shape of the matrix-shaped trench 4 that defines and surrounds the cell blocks 6 may have a variety FIG. 5 shows an example thereof, in which the y trenches extend along non-offset straight lines.

Further, numbers and arrangement densities of the emitter regions 14 and the body contact regions 16 provided in the surrounding block 18 may be adjusted in variations as needed. FIG. 5 shows an example in which one emitter region 14 and one body contact region 16 in the surrounding block 18 are provided corresponding to every other cell blocks 6. In accordance with the need, the arrangement density of the emitter regions 14 and the body contact regions 16 in the surrounding block 18 to be provided at positions connecting to the x trenches and the arrangement density of the emitter regions 14 and the body contact regions 16 in the surrounding block 18 to be provided at positions connecting to the y trenches may be changed. The arrangement density of the emitter regions 14 and the body contact regions 16 to be provided in the surrounding block 18 may be changed so as to obtain the required breakage resisting strength.

An arrangement relationship of the emitter regions 8 and the body contact regions 10 in the cell blocks 6 may have a variation. In the embodiment of FIG. 5, the emitter regions 8 are provided not only at positions connecting to the y trenches, but also at positions connecting to the x trenches.

### Third Embodiment

FIG. 6 shows an example in which one x trench 4a is provided on an outer side of the outermost x trench in the y direction. In this case, the surrounding block 18 is arranged in between the outermost x trench in the y direction and the x trench 4a provided on the outer side thereof. In the present embodiment, the emitter regions 14 and the body contact regions 16 are provided in this surrounding block 18. The arrangement relationship of the emitter regions 14 and the body contact regions 16 may have a variation, and in the example shown in FIG. 6, the emitter region 14 and the body contact region 16 are adjacent to each other in pairs along the x direction. Further, the emitter regions 14 and the body contact regions 16 extend continuously between the outermost x trench 4 in the y direction and the x trench 4a provided on the outer side thereof. Whether or not the emitter regions 14 and the body contact regions 16 extend to reach the x trench 4a may variously be determined, and they may not reach the x trench 4a.

### Fourth Embodiment

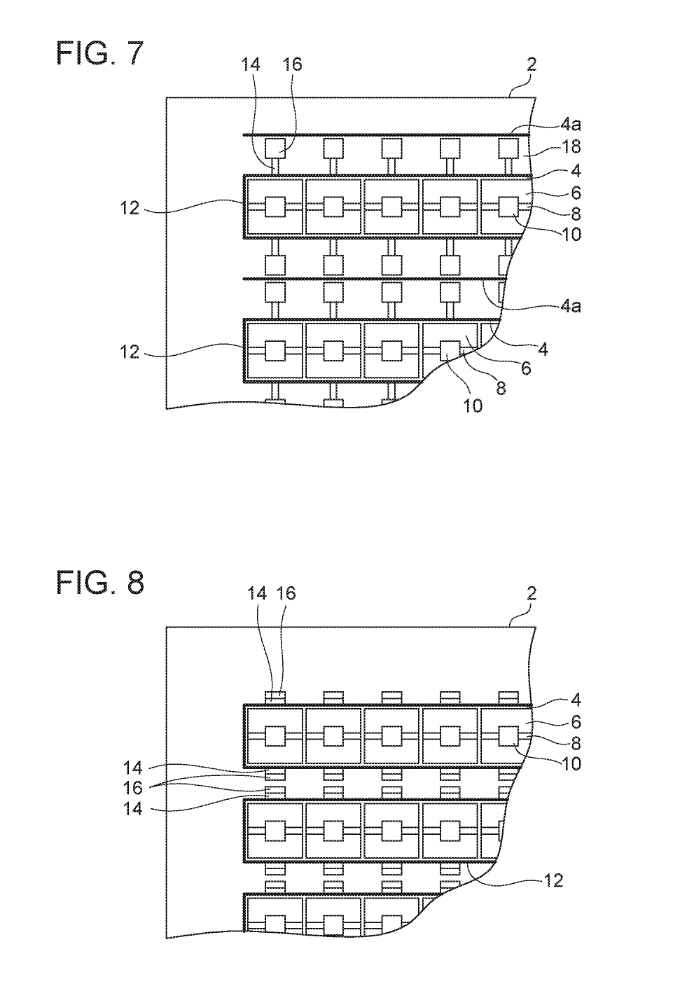

FIG. 7 shows an example in which a plurality of matrix trenches, in each of which plural cell blocks 6 are arranged consecutively in the x direction, is repeatedly provided at intervals in the y direction, with one x trench 4a extending in each of the intervals. In other words, a plurality of matrix trenches, in each of which plural cell blocks 6 are arranged consecutively in the x direction, is provided by being separated from each other with intervals in the y direction, with one x trench 4a extending in each of the intervals. In the present embodiment, intervals between each of the matrix trenches and its corresponding x trench 4a become the surrounding block 18, and the emitter regions 14 and the body contact regions 16 are provided in this surrounding block 18.

The arrangement densities of the emitter regions 14 and the body contact regions 16 provided in the surrounding block 18 may have a variation, and in FIG. 7, the emitter regions 14 and the body contact regions 16 are provided for each cell block 6; however, the arrangement densities thereof may be sparser. When the total area of the emitter regions 8 in the cell blocks 6 is greater than the total area of the emitter regions 14 in the surrounding block 18, the total area of the cell blocks 6 is greater than the total area of the surrounding block 18, and the area ratio of the emitter regions 8 in the cell blocks 6 is greater than the area ratio of the emitter regions 14 in the surrounding block 18, these relationships bring forth an IGBT with low on-voltage and high breakage resistance.

### Fifth Embodiment

In FIG. 8, the straight line-shaped trenches 4a extending in the x direction in the y intervals between the matrix trenches are omitted. In this case as well, the formation of the emitter regions 14 and the body contact regions 16 in the surrounding block 18 is advantageous, by which the hole accumulating phenomenon can be suppressed.

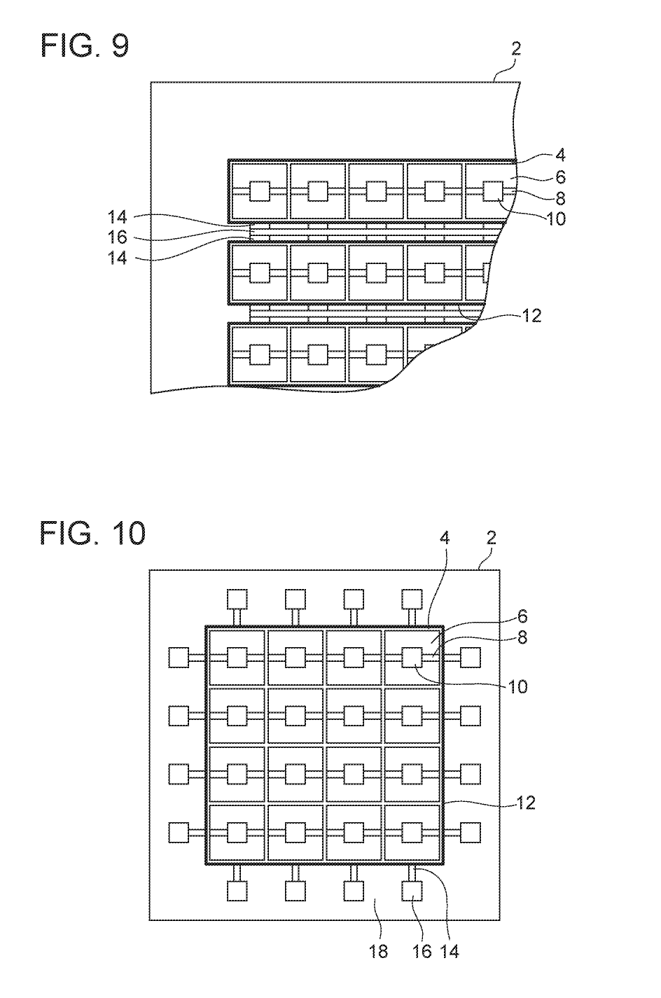

As shown in FIG. 9, the body contact regions 16 may extend long in the x direction, so that each of them can be shared among plural cell blocks 6.

In the cases of FIG. 7 and FIG. 8, each of the matrix-shaped trenches is configured of two x trenches extending in the x direction with a predetermined interval (y interval) in the y direction and a plurality of y trenches extending in the y direction between the aforementioned two x trenches with predetermined intervals (x intervals) in the x direction. According to these matrix-shaped trenches, the plural cell blocks 6 arranged along the x trenches are arranged repeatedly, i.e., in rows. In the cases of FIG. 7 and FIG. 8, the emitter regions 14 of the surrounding block 18 are provided at positions corresponding respectively to all of the cell blocks 6. Similarly, the body contact regions 16 of the surrounding block 18 are provided at positions corresponding respectively to all of the cell blocks 6. According to the above, the carrier concentrations in the cell blocks 6 and the surrounding block 18 are equalized, and the breakage resistance is thereby improved.

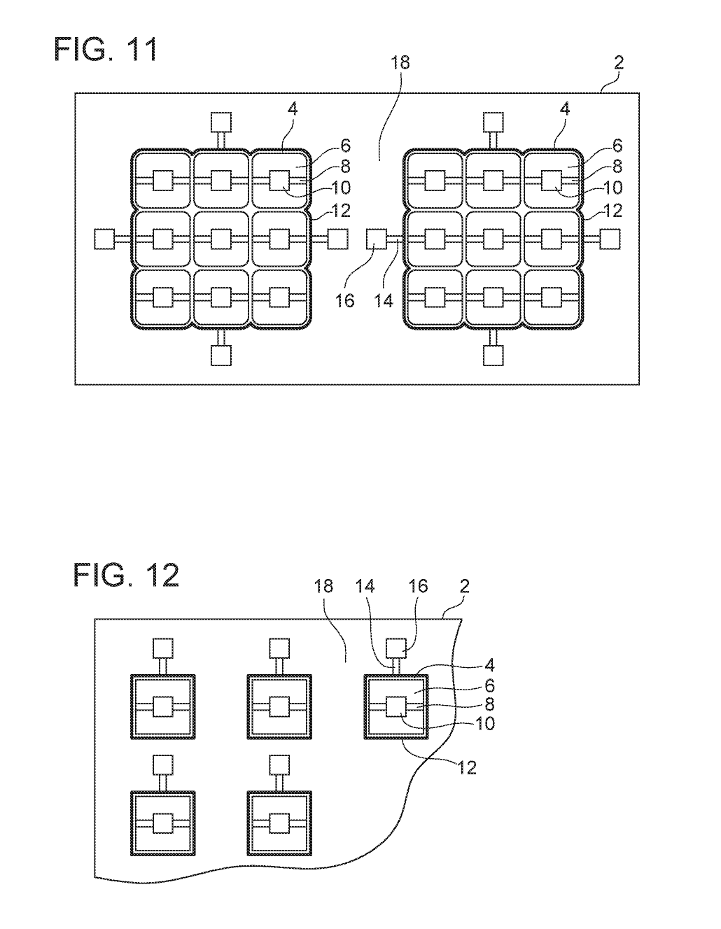

FIG. 10 to FIG. 12 show examples of a relationship between the cell blocks 6 and the contour 12 that define the range where the cell blocks 6 are arranged consecutively. FIG. 10 shows an example in which the cell blocks 6 are arranged in a 4×4 matrix in the contour 12. FIG. 11 shows an example in which two contours 12, each of which contains 3×3 cell blocks 6, are arranged within the same semiconductor substrate. FIG. 12 shows a case where a plurality of cell blocks 6 is arranged within the same semiconductor substrate however the cell blocks 6 are not arranged consecutively, and are separated from each other, In this case, a relationship is obtained in which one cell block 6 exists within each contour 12. The surrounding block to be described in such a case refers to a region on the outer side of the contour(s) 12 that define the range(s) where the cell block(s) 6 are to be arranged separately, instead of referring to the outer side of the matrix-shaped trench that defines each cell block 6.

The arrangement densities of the emitter regions 14 and the body contact regions 16 that need to be provided in the surrounding block 18 differ depending on the number or the like of the cell blocks 6 to be included in the contour(s) 12. In FIG. 10, four cell blocks 6 are included in the contour 12 in the x direction, and the emitter regions 14 and the body contact regions 16 are provided in pairs in the surrounding block 18 at the positions corresponding respectively to all of the cell blocks 6. The same applies to its configuration in the y direction.

In the example of FIG. 11, a case where three cell blocks 6 are included in each contour 12 in the x direction, and the emitter regions 14 and the body contact regions 16 are provided in pairs in the surrounding block 18 at the positions corresponding to the cell blocks 6 in the centers of the contours 12. In this case, an example is shown in which the required breakage resistance can be ensured by providing the emitter regions 14 and the body contact regions 16 in the surrounding block 18 corresponding to the center cell blocks 6.

In the example of FIG. 12, a case where one cell block 6 is included in each contour 12, and pairs of the emitter regions 14 and the body contact regions 16 are provided in the surrounding block 18 so that each pair corresponds to one of the contours 12. In this case, an example is shown in which the required breakage resistance can be ensured by providing the one pair of emitter region 14 and body contact region 16 in the surrounding block 18 for each of the contours 12.

In the case of FIG. 12 as well, the relationship: the area of the cell blocks 6 existing around the emitter regions 8<the area of the surrounding block 18 existing around the emitter regions 14 is satisfied, the area ratio of the emitter region occupying the blocks is high for the cell blocks 6 and low for the surrounding block 18. All of the embodiments satisfy this relationship.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously; and satisfying any one of those objectives gives technical utility to the present invention.

What is claimed is:

1. An IGBT (Insulated Gate Bipolar Transistor) comprising:
a semiconductor substrate:
an emitter electrode provided on a front surface of the semiconductor substrate; and
a collector electrode provided on a back surface of the semiconductor substrate,
wherein the semiconductor substrate comprises emitter regions of a first conductive type that are electrically connected to the emitter electrode; a collector region of a second conductive type that is electrically connected to the collector electrode; a drift region of the first conductive type that is separated from the collector electrode by the collector region; and a body region of the second conductive type that separates the emitter region and the drift region,
the semiconductor substrate further comprises a trench extending from the front surface of the semiconductor substrate and reaching the drift region,
the trench partitions the front surface of the semiconductor substrate into a plurality of blocks in a plan view of the semiconductor substrate,
the plurality of the blocks comprises cell blocks, each of which is partitioned to be equal to or smaller than a predetermined area by the trench, and a surrounding block which is a region other than the cell blocks,
wherein the collector region, the drill region, the body region and the emitter region are provided in each of the cell blocks and the surrounding block, and
a total area of the emitter regions in the cell blocks is greater than a total area of the emitter region in the surrounding block in the plan view of the semiconductor substrate.

2. The IGBT according to claim 1, wherein
a total area of the cell blocks is greater than a total area of the surrounding block in the plan view of the semiconductor substrate.

3. The IGBT according to claim 1, wherein
in the plan view of the semiconductor substrate, an area ratio of the emitter regions in blocks is high in the cell blocks and low in the surrounding block.

4. The IGBT according to any one of claims 1, wherein
two directions that are perpendicular to each other in the plan view of the semiconductor substrate are defined as an x direction and a y direction,
the trench comprises a plurality of x trenches extending in the x direction and spaced apart at predetermined y intervals in the y direction, and a plurality of y trenches extending in the y direction between respective adjacent x trenches and spaced apart at predetermined x intervals in the x direction,
positions in the x direction of the y trenches that are adjacent in the y direction are offset from each other by ½ of the x interval,
the emitter regions of the cell blocks are provided at positions connecting to the y trenches,
the emitter region of the surrounding block is provided at a position connecting to at least one of the outermost x trenches.

5. The IGBT according to claim 4, wherein
the emitter region of the surrounding block is provided at an intermediate position between two y trenches that are adjacent in the x direction.

6. The IGBT according to any one of claims 1, wherein
two directions that are perpendicular to each other in the plan view of the semiconductor substrate are defined as an x direction and a y direction,
the trench comprises a plurality of x trenches extending in the x direction and spaced apart at predetermined y intervals in the y direction,
the cell blocks are arranged consecutively along each of the x trenches, and
the surrounding block comprises a plurality of the emitter regions, the emitter region being provided at a position corresponding respectively to each of the cell blocks.

7. The IGBT according to any one of claims 1, wherein
a contour defining a range where a plurality of the cell blocks is arranged consecutively is square-shaped, and at least the emitter region of the surrounding block is provided on each side of the contour.
